(19) United States
(12) Patent Application Publication
(10) Pub. No.: US 2025/0234644 A1
(43) Pub. Date: Jul. 17, 2025

(54) SEMICONDUCTOR DEVICE INCLUDING RESISTANCE-CAPACITANCE (RC) STRUCTURE

(71) Applicant: SAMSUNG ELECTRONICS CO., LTD., SUWON-SI (KR)

(72) Inventors: Kibum Nam, Suwon-si, Gyeonggi-do (KR); Garoom Kim, Suwon-si, Gyeonggi-do (KR); Bonghyun Lee, Suwon-si (KR); Ilkwon Lee, Suwon-si, Gyeonggi-do (KR); Junyoung Lee, Suwon-si, Gyeonggi-do (KR)

(21) Appl. No.: 18/756,583

(22) Filed: Jun. 27, 2024

(30) Foreign Application Priority Data
Jan. 15, 2024 (KR) 10-2024-0006192

(51) Int. Cl. H01L 27/118

(52) U.S. Cl. CPC H10D 84/907; H10D 84/925; H10D 84/975; H10D 84/981

(57) ABSTRACT

A semiconductor device includes: a plurality of standard cells disposed on a frontside of a substrate, and respectively including at least one gate structure and at least one active region; a frontside buffer cell disposed on the frontside of the substrate and between at least some of the plurality of standard cells, and including at least one a Through-Silicon Via (TSV) penetrating through the substrate; and a backside buffer cell disposed on a backside of the substrate, which includes: a plurality of conductive layers disposed on the backside of the substrate; and a plurality of vias connecting the plurality of conductive layers; and an insulating layer surrounding the plurality of conductive layers and the plurality of vias, wherein each of the plurality of conductive layers includes signal conductive patterns electrically connected to the at least one TSV, and power conductive patterns electrically connected to a power source.

### CROSS-REFERENCE TO RELATED APPLICATION(S)

This application claims priority under 35 U.S.C. § 119 to Korean Patent Application No. 10-2024-0006192 filed on Jan. 15, 2024, in the Korean Intellectual Property Office, the disclosure of which is herein incorporated by reference in its entirety.

### TECHNICAL FIELD

The present disclosure relates to a semiconductor device, and more particularly to a semiconductor device including a Resistance-Capacitance (RC) structure.

### DESCRIPTION OF RELATED ART

An input unit, such as a flip-flop, of an integrated circuit may capture a data value of a signal. The input unit of the integrated circuit may store the data value for a hold time, which may be a time for which the data value will be held in the input unit. When the hold time of the data value is short, timing conflicts may occur, and inaccurate data values may be captured by the input unit. To ensure the hold time of data values, a signal input to the input unit may be delayed by using a hold buffer in a signal path of the signal.

A hold buffer may be used in an integrated circuit to store an input of a device at a last known state. The hold buffer may be implemented using transistor components. Implementing the hold buffer in the integrated circuit may cause an increased circuit area and increased power consumption. Further, a Process-Voltage-Temperature (PVT) variation of the hold buffer may make it difficult to design the integrated circuit.

### SUMMARY

An aspect of the present disclosure is to provide a semiconductor device that may ensure a hold time of a data value and that may suppress an increase in a circuit area.

An aspect of the present disclosure is to provide a semiconductor device that may reduce power consumption and reduce a design constraint.

According to an aspect of the present disclosure, a semiconductor device may include: a plurality of standard cells disposed on a frontside of a substrate, and respectively including at least one gate structure and at least one active region; a frontside buffer cell disposed on the frontside of the substrate and between at least some of the plurality of standard cells and including at least one a Through-Silicon Via (TSV) penetrating through the substrate; and a backside buffer cell disposed on a backside of the substrate, wherein the backside buffer cell may include: a plurality of conductive layers disposed at different levels on the backside of the substrate, a plurality of vias connecting the plurality of conductive layers between the plurality of conductive layers, an insulating layer between the plurality of conductive layers and the plurality of vias, and wherein each of the plurality of conductive layers may include signal conductive patterns electrically connected to the at least one TSV, and power conductive patterns electrically connected to a power source.

According to an aspect of the present disclosure, a semiconductor device may include a substrate; a Through-Silicon Via (TSV) penetrating through the substrate and electrically connected to an output terminal of a first flip-flop disposed on a frontside of the substrate and an input terminal of a second flip-flop disposed on the frontside of the substrate; and a Resistance-Capacitance (RC) structure disposed on a backside of the substrate, wherein the RC structure may include: a plurality of conductive layers respectively including a plurality of conductive patterns; a plurality of vias connecting the plurality of conductive patterns between the plurality of conductive layers; and an insulating layer between the plurality of conductive layers, wherein conductive patterns of neighboring conductive layers, among the plurality of conductive layers, may extend in directions intersecting each other, and the conductive patterns of each of the plurality of conductive layers may include signal conductive patterns electrically connected to the TSV, and power conductive patterns electrically connected to a power source, and the signal conductive patterns and the power conductive patterns may be arranged alternately.

According to an aspect of the present disclosure, a semiconductor device may include: a substrate; a first Through-Silicon Via (TSV) penetrating through the substrate and connected to an output terminal of a first flip-flop disposed on a frontside of the substrate; a second TSV penetrating through the substrate and connected to an input terminal of a second flip-flop disposed on the frontside of the substrate; and a Resistance-Capacitance (RC) structure disposed on a backside of the substrate, wherein the RC structure may include: a plurality of conductive layers stacked on the backside of the substrate and respectively including a plurality of conductive patterns; a plurality of vias connecting a plurality of conductive patterns between the plurality of conductive layers; and an insulating layer between the plurality of conductive layers and the plurality of vias, wherein conductive patterns of neighboring conductive layers of the plurality of conductive layers, may extend in directions intersecting each other, and the plurality of conductive layers may include signal conductive patterns electrically connected to the first TSV and the second TSV and power conductive patterns electrically connected to a power source.

A semiconductor device according to an example embodiment of the present disclosure includes an RC structure formed on a backside of a substrate and connected to a terminal formed on a frontside of the substrate through a Through-Silicon Via (TSV) penetrating through the substrate, as a hold buffer.

A semiconductor device according to an example embodiment of the present disclosure may reduce power consumption by providing the RC structure as a hold buffer, and facilitate design by reducing PVT deviation.

The aspects of the present disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating an integrated circuit according to an example embodiment of the present disclosure;

FIG. 2 is a view schematically illustrating a hold buffer according to an example embodiment of the present disclosure;

FIG. 3 is a view illustrating a hold buffer in detail according to an example embodiment of the present disclosure;

FIG. 4 is a view illustrating an equivalent circuit of the hold buffer of FIG. 3;

FIG. 5 is a view schematically illustrating a hold buffer according to an example embodiment of the present disclosure;

FIG. 6 is a view illustrating a hold buffer in detail according to an example embodiment of the present disclosure;

FIG. 7 is a view illustrating an equivalent circuit of the hold buffer of FIG. 6;

FIG. 8A and FIG. 8B are cross-sectional views illustrating a portion of a semiconductor device according to example embodiments of the present disclosure;

FIG. 9 is a plan view illustrating a backside of a semiconductor device according to an example embodiment of the present disclosure;

FIG. 10A and FIG. 10B are cross-sectional views taken along line I-I′ and II-II′ of FIG. 9, respectively;

FIG. 11 is a plan view illustrating a backside of a semiconductor device according to an example embodiment of the present disclosure;

FIG. 12 is a plan view illustrating a frontside of a semiconductor device according to an example embodiment of the present disclosure; and

FIG. 13 is a plan view illustrating a backside of a semiconductor device according to an example embodiment of the present disclosure.

### DETAILED DESCRIPTION

In the following detailed description, reference is made to the accompanying drawings that show, by way of illustration, embodiments in which the invention may be practiced. Embodiments are described in sufficient detail to enable those skilled in the art to practice the invention. It is to be understood that various embodiments of the invention, although different, are not necessarily mutually exclusive. For example, a certain feature, structure, or characteristic described herein in connection with one embodiment may be implemented within other embodiments without departing from the spirit and scope of the invention. In addition, it is to be understood that the location or arrangement of individual elements within each embodiment may be modified without departing from the spirit and scope of the invention. The following detailed description is, therefore, not to be taken in a limiting sense, and the scope of the present inventive concept is defined only by the appended claims, appropriately interpreted, along with the full range of equivalents to which the claims are entitled. In the drawings, like numerals refer to the same or similar elements or functionality throughout the several views.

Hereinafter, example embodiments of the present disclosure will be described with reference to the accompanying drawings.

Integrated circuits are known which use a data processing circuit configured to process a data signal passing along a signal path, and a clock circuit coupled to the data processing circuit to control the passage of the data signal along the signal path using a clock signal. These integrated circuits may have various forms, but typically the signal path may include components such as flip-flops that capture and store data values in synchronization with the clock signal.

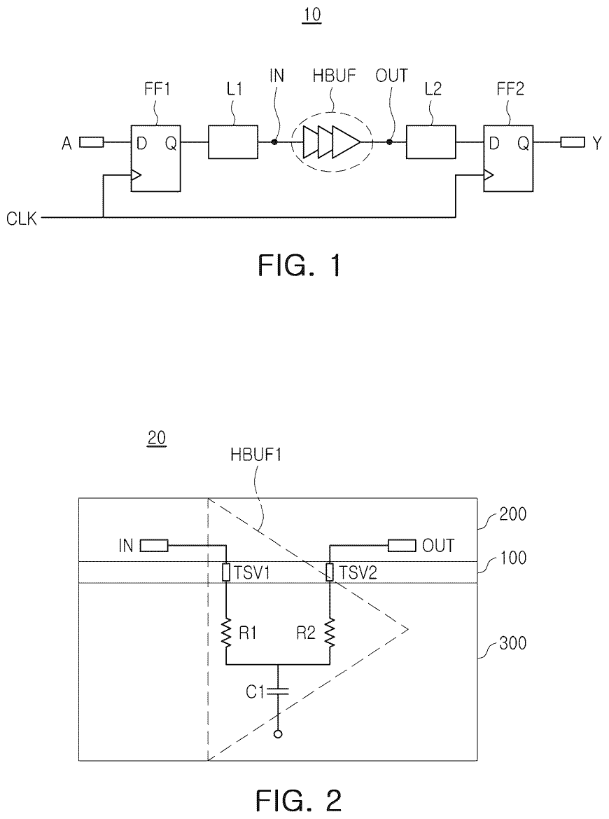

FIG. 1 is a view illustrating an integrated circuit according to an example embodiment of the present disclosure.

Referring to FIG. 1, an integrated circuit 10 may include a signal path from terminal A, which is an input terminal, to terminal Y, which is an output terminal. The signal path may include a first flip-flop FF1, a second flip-flop FF2, a first load L1, a second load L2, and a hold buffer HBUF.

The first flip-flop FF1 may receive a data signal from terminal A. The first flip-flop FF1 may receive a clock signal CLK. The first flip-flop FF1 may be synchronized to the clock signal CLK to capture and store a data signal. The first flip-flop FF1 may output the stored data signal to the second flip-flop FF2. The second flip-flop FF2 may receive the clock signal CLK. The second flip-flop FF2 may be synchronized with the clock signal CLK to capture and store the data signal received from the first flip-flop FF1, and may output the stored data signal to terminal Y.

The second flip-flop FF2 may capture a correct data value from a signal in a case that the setup time and hold time in an input unit of the second flip-flop FF2 of the data signal may be ensured. The setup time may refer to the time during which a data value of a signal may need to be maintained before an active edge of the clock signal CLK is applied to the second flip-flop FF2. The hold time may refer to the time for which the data value of the signal may need to be maintained after the active edge of the clock signal CLK.

The hold buffer HBUF of the integrated circuit 10 may ensure the setup time and the hold time for the second flip-flop FF2. The hold buffer HBUF may delay a data signal output from the first flip-flop FF1 for a predetermined period and may output the data signal to the second flip-flop FF2 after the delay. The first load L1 and the second load L2 may be arbitrary load components. The first load L1 may be disposed between the first flip-flop FF1 and the hold buffer HBUF. The second load L2 may be disposed between the hold buffer HBUF and the second flip-flop FF2. For example, the hold buffer HBUF may be disposed between the first load L1 and the second load L2.

As the complexity of the integrated circuit 10 increases, the integrated circuit 10 may include a plurality of hold buffers to match the timing of data signals. For example, the hold buffer may be included to the clock circuit to intentionally generate a clock skew between the clock signal applied to the first flip-flop FF1 and the clock signal applied to the second flip-flop FF2. With the inclusion of additional hold buffers, an area of the integrated circuit 10 may increase and may cause increased power consumption.

Additionally, when the integrated circuit 10 includes a plurality of hold buffers, a turnaround time (TAT) for designing the integrated circuit 10 may increase. For example, for hold buffers including transistors, a Process-Voltage-Temperature (PVT) variation between different ones of the hold buffers may increase. In order for an integrated circuit to be designed so that each of the plurality of hold buffers may ensure the setup time and the hold time, even under a wide range of PTV conditions, several design modifications and operational verifications may need to be performed.

According to an example embodiment of the present disclosure, a semiconductor device including an integrated circuit may include an RC (Resistance-Capacity) structure. The RC structure may provide an RC delay to a backside of a substrate. For example, the RC structure may include a mesh-shaped metal structure (e.g., a metal mesh) and an insulating layer included within the metal structure. For example, the mesh-shared metal structure may include a plurality of metal layers and the RC structure may be disposed between the method layers. Additionally, the RC structure may be connected to an output unit of the first flip-flop FF1 and an input unit of the second flip-flop FF2 through a Through-Silicon Via (TSV) penetrating through the substrate, and may from a hold buffer for the data signal provided to the second flip-flop.

According to an example embodiment of the present disclosure, a structure that provides a delay of a hold buffer may be formed on the backside of the substrate. In a case that the hold buffer may be formed on the backside of the substrate, an area of the integrated circuit may be improved. Additionally, the integrated circuit including the RC structure may have a lower power consumption while providing a same delay as compared to a hold buffer including a semiconductor device. Further, the integrated circuit including the RC structure may have a low level of PVT deviation. Accordingly, the power consumption of the semiconductor device may be improved, and TAT for designing the semiconductor device may also be reduced. Hereinafter, a hold buffer according to an example embodiment of the present disclosure is described in detail.

FIG. 2 is a view briefly illustrating a hold buffer according to an example embodiment of the present disclosure.

A semiconductor device 20 may include a substrate 100. The substrate may have an upper surface unit 200 and at a lower surface unit 300. Components of the hold buffer HBUF1 may be disposed in a substrate 100, in the upper surface unit 200 at a frontside of the substrate 100, and on a lower surface unit 300 at a backside of the substrate 100.

The substrate 100 may be a Si substrate. Semiconductor components may be formed on the upper surface unit 200 of the substrate 100. The semiconductor components may be electrically connected through conductive patterns formed on a frontside, thereby forming an integrated circuit. For example, semiconductor components may form flip-flops such as those described with reference to FIG. 1. The upper surface unit 200 may include the semiconductor components and conductive patterns.

Metal wires may also be formed on the lower surface unit 300 of the substrate 100. For example, the lower surface unit 300 may include metal wires that form a power distribution network (PDN) of the semiconductor device 20.

The upper surface unit 200 and the lower surface unit 300 may be electrically connected through a TSV penetrating through the substrate 100. For example, the PDN may supply power to the upper surface unit 200 through the TSV.

According to an example embodiment of the present disclosure, the hold buffer HBUF1 may include terminals disposed on the upper surface unit 200, TSVs penetrating through the substrate 100, and an RC structure disposed on the lower surface unit 300 and configured to provide the RC delay.

For example, the upper surface unit 200 may include an input terminal IN of the hold buffer HBUF1 and an output terminal OUT of the hold buffer HBUF1. The input terminal IN of the hold buffer HBUF1 may be connected to the output terminal of the first flip-flop FF1 described with reference to FIG. 1, and the output terminal OUT of the hold buffer HBUF1 may be connected to the input terminal of the second flip-flop FF2 described with reference to FIG. 1.

The substrate 100 may include a first TSV TSV1 connected to the input terminal IN and a second TSV TSV2 connected to the output terminal OUT. Additionally, the RC structure disposed on the lower surface unit 300 may be electrically connected to the input terminal IN and the output terminal OUT of the hold buffer HBUF1 through the first and second TSVs (TSV1 and TSV2). In an example of FIG. 2, the RC structure is illustrated as an equivalent circuit including a first resistor R1, a second resistor R2, and a first capacitor C1. Depending on a design of the RC structure, the parameters of the first resistor R1, the second resistor R2, and the first capacitor C1 may vary, and the RC delay provided by the hold buffer HBUF1 may vary. For example, resistance parameters of the first resistor R1 and the second resistor R2, and a capacitance parameter of the first capacitor C1 may vary, and the RC delay provided by the hold buffer HBUF1 may vary.

In a case where the hold buffer is configured using semiconductor components, with as a delay that the hold buffer is configured to provide increases, the hold buffer may include a greater number of semiconductor components, and an area occupied by the hold buffer on the frontside of the substrate may increase. In a case where the hold buffer HBUF1 is configured using the RC structure of the lower surface unit 300 according to an example embodiment of the present disclosure, even if the delay that the hold buffer HBUF1 is configured to provide is increased, the hold buffer may occupy a fixed-sized area in which terminals are formed, at the upper surface unit 200.

According to an example embodiment of the present disclosure, the area occupied by the hold buffer(s) HBUF1 included in the semiconductor device 20 on the upper surface unit 200 may be low, and a circuit formed of semiconductor components may be highly integrated on the upper surface unit 200.

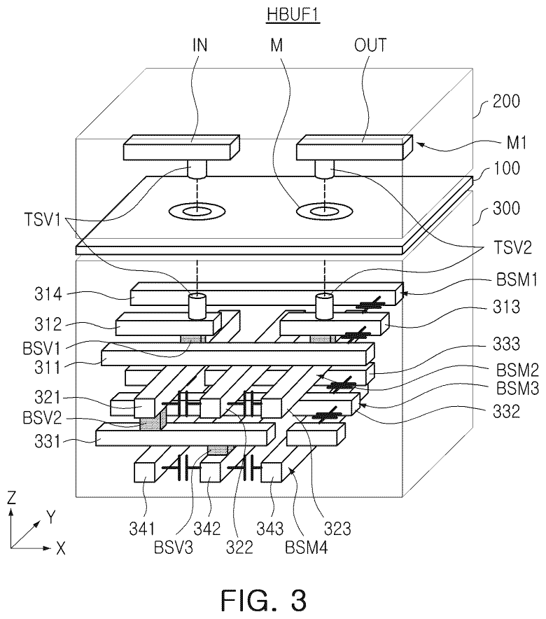

FIG. 3 is a view illustrating in detail a hold buffer according to an example embodiment of the present disclosure.

A hold buffer HBUF1 illustrated in FIG. 3 may correspond to the hold buffer HBUF1 described with reference to FIG. 2. Referring to FIG. 3, the upper surface unit 200 may include an input terminal IN and an output terminal OUT. The input terminal IN and the output terminal OUT may be provided by metal wires M1. The input terminal IN may be electrically connected to an RC structure by a first TSV TSV1. The output terminal OUT may be electrically connected to an RC structure by a second TSV TSV2. The first TSV TSV1 and the second TSV TSV2 may each penetrate through the substrate 100. FIG. 3 also illustrates a metal M penetrating through the substrate 100 and formed around the first TSV TSV1 and the second TSV TSV2.

The RC structure may include first conductive pattern BSM1, second conductive pattern BSM2, third conductive pattern BSM3, and fourth conductive pattern BSM4. The RC structure may include first vias BSV1, second vias BSV2, and third vias BSV3. The first to fourth conductive patterns BSM1, BSM2, BSM3, and BSM4, and the first to third vias BSV1, BSV2, and BSV3 may be alternately stacked on the substrate 100 in a direction opposite to a third direction (Z-direction). The first to fourth conductive patterns BSM1 to BSM4 may be disposed on different levels of conductive layers. For example, the first conductive patterns BSM1 may be disposed on an uppermost layer, and the fourth conductive patterns BSM4 may be disposed on a lowermost layer.

The first to fourth conductive patterns BSM1 to BSM4 may extend in intersecting directions in which conductive patterns disposed in neighboring conductive layers intersect each other. For example, the first conductive pattern BSM1 may extend in a first direction (X-direction) and the second conductive pattern BSM2 may extend in a second direction (Y-direction) intersecting the first direction. The first conductive patterns BSM1 may be spaced apart from each other in the second direction (Y-direction) and extend in a first direction (X-direction) intersecting the second direction (Y-direction). The second conductive patterns BSM2, neighboring the first conductive patterns BSM1, may be spaced apart from each other in the first direction (X-direction) and extend in the second direction (Y-direction). The third conductive patterns BSM3, neighboring the second conductive patterns BSM2, may be spaced apart in the second direction (Y-direction) and extend in the first direction (X-direction). The fourth conductive patterns BSM4, neighboring the third conductive patterns BSM3, may be spaced apart in the first direction (X-direction) and extend in the second direction (Y-direction).

In an example of FIG. 3, a first conductive patterns BSM1 disposed on an uppermost layer of the lower surface unit 300 may extend in a direction, parallel to a metal wire M1 disposed on a lowermost layer of the upper surface unit 200. However, the present disclosure is not limited thereto.

The RC structure may include signal conductive patterns and power conductive patterns. The signal conductive patterns may be connected to a data path. The power conductive patterns may be connected to a power source. For example, the power source may be VDD power or VSS power. In each conductive layer, the signal conductive patterns and the power conductive patterns may be arranged alternately with each other.

For example, the first conductive patterns BSM1 may include power conductive patterns 311 and 314 connected to the power source, and a signal conductive pattern 312 connected to the input terminal IN through the first TSV TSV1, and a signal conductive pattern 313 connected to the output terminal OUT through the second TSV TSV2.

The second conductive patterns BSM2 may include a power conductive pattern 322 connected to the power source, a signal conductive pattern 321 connected to the signal conductive pattern 312 through the first vias BSV1, and a signal conductive pattern 323 connected to the signal conductive pattern 313 through the first vias BSV1.

The third challenge patterns BSM3 may include a signal conductive pattern 331 connected to the signal conductive pattern 321 through the second vias BSV2, a power conductive pattern 332 connected to the power source, and a signal conductive pattern 333 connected to the signal conductive pattern 323 through the second vias BSV2.

Additionally, the fourth conductive patterns BSM4 may include power conductive patterns 341 and 343 connected to the power source, and a signal conductive pattern 342 connected to the signal conductive patterns 331 and 333 through third vias BSV3.

In FIG. 3, electrical connections between the power conductive patterns 311, 314, 322, 332, 341 and 343 may be omitted. The power conductive patterns 311, 314, 322, 332, 341 and 343 may be connected to each other through vias (not illustrated), each of which may be electrically connected to a power rail. For example, while a second via of the second vias BSV2 is illustrated in FIG. 3 connecting the signal conductive pattern 331 and the signal conductive pattern 321, this is not limiting, and additional second vias of the second vias BSV2 may be formed in the RC structure as described herein.

An insulating layer may be disposed surrounding the signal conductive patterns and the power conductive patterns of the RC structure. The signal conductive patterns may include resistance components. The signal conductive patterns, the insulating layers, and the power conductive patterns may provide capacitance.

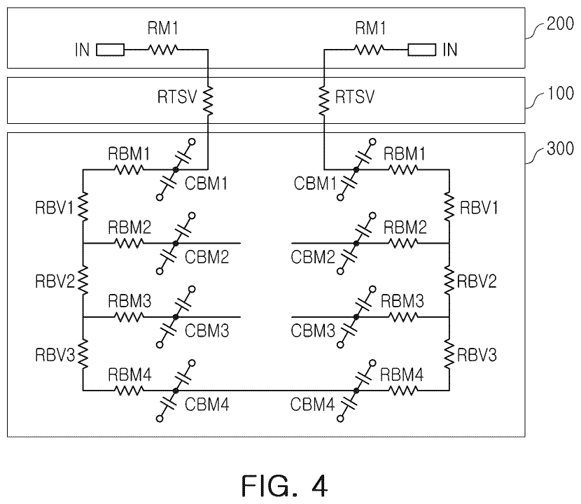

FIG. 4 is a view illustrating an equivalent circuit of the hold buffer of FIG. 3.

Referring to FIG. 3 and FIG. 4 together, the metal wires M1 providing the input terminal IN and the output terminal OUT may form resistance components RM1. Additionally, the first TSV TSV1 and the second TSV TSV2 may form resistance components RTSV.

The first conductive pattern BSM1 may include first resistance components RBM1. The second conductive pattern BSM2 may include second resistance components RBM2. The third conductive pattern BSM3 may include third resistance components RBM3. The fourth conductive pattern BSM4 may include fourth resistance components RBM4. The first vias BSV1 connected to the signal conductive patterns may include first resistance components RBV1. The second vias BSV2 connected to the signal conductive patterns may include second resistance components RBV2. The third vias BSV3 connected to the signal conductive patterns may include third resistance components RBV3.

The signal conductive patterns and power conductive patterns included in the first conductive patterns BSM1 may provide first capacitances CBM1 together with an insulating layer between the first conductive patterns BSM1. Similarly, the second conductive pattern BSM2 may provide second capacitances CBM2 together with an insulating layer between the second conductive pattern BSM2. The third conductive pattern BSM3 may provide third capacitances CBM3 together with an insulating layer between the third conductive pattern BSM3. The fourth conductive pattern BSM4 may provide fourth capacitances CBM4 together with an insulating layer between the fourth conductive pattern BSM4.

The resistance components and capacitances illustrated in FIG. 4 may provide an RC delay between the input terminal IN and the output terminal OUT.

In the examples of FIG. 3 and FIG. 4, the signal conductive patterns 312 and 313, among the first conductive patterns BSM1, may be physically separated, the signal conductive patterns 321 and 323, among the second conductive patterns BSM2, may be physically separated, and the signal conductive patterns 331 and 333, among the third conductive patterns BSM3, may be physically separated. The signal conductive patterns 312, 321 and 331 connected to the input terminal IN and the signal conductive patterns 313, 323 and 333 connected to the output terminal OUT may be electrically connected through the signal conductive pattern 342.

That is, in the remaining conductive layers except for a lowermost conductive layer, disposed away from the substrate 100, among the conductive layers forming the RC structure, the first signal conductive patterns connected to the first TSV TSV1 and the second signal conductive patterns connected to the second TSV TSV2 may be separated from each other. Additionally, the first signal conductive patterns and the second signal conductive patterns may be electrically connected through the signal conductive pattern included in the lowermost conductive layer.

According to an example embodiment of the present disclosure, the signal conductive patterns 312, 321 and 331 connected to the first TSV TSV1 and the signal conductive patterns 313, 323 and 333 connected to the second TSV TSV2 may be physically separated from each other, which may enable the hold buffer HBUF1 to provide a high resistance component and a high RC delay. For example, the hold buffer HBUF1 may provide a higher resistance component and a higher RC delay as compared to a case in which the signal conductive patterns of the first to third conductive patterns BSM1 to BSM3 are physically connected to each other.

However, the present disclosure is not limited to a case in which the signal conductive patterns of the first to third conductive patterns BSM1 to BSM3 are physically separated from each other. For example, to provide a set RC delay, the hold buffer may have a structure in which at least some of the signal conductive patterns of the first to third conductive patterns BSM1 to BSM3 may be physically connected to each other.

According to an example embodiment of the present disclosure described with reference to FIG. 3 and FIG. 4, the RC structure of the hold buffer HBUF1 may include four layers of conductive patterns BSM1 to BSM4. However, the present invention is not limited thereto. For example, the hold buffer may include conductive patterns included in three or less conductive layers, or may include conductive patterns included in five or more conductive layers.

According to an example embodiment of the present disclosure described with reference to FIG. 2, FIG. 3, and FIG. 4, the hold buffer HBUF1 may include the first TSV TSV1 connected to the input terminal IN and the second TSV TSV2, connected to the output terminal OUT. However, the present disclosure is not limited thereto. For example, the hold buffer may include one TSV connected to the input terminal IN and the output terminal OUT, or may include three or more TSVs. Hereinafter, an example of a hold buffer including one TSV is described in detail.

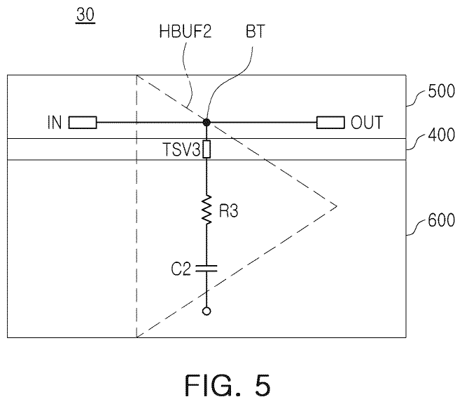

FIG. 5 is a view illustrating a hold buffer according to an example embodiment of the present disclosure.

A hold buffer HBUF2 may be provided across a substrate 400, an upper surface unit 500 at a frontside of a semiconductor device 30, and a lower surface unit 600 at a backside of the semiconductor device 30.

Similar to that described with reference to FIG. 2, the substrate 400 may be a Si substrate on which semiconductor components are formed on the frontside. The upper surface unit 500 may include the semiconductor components and conductive patterns that electrically connect the semiconductor components. Additionally, metal wires may also be included in the lower surface unit 600. The upper surface unit 500 and the lower surface unit 600 may be electrically connected through a TSV penetrating through the substrate 400.

According to an example embodiment of the present disclosure, the hold buffer HBUF2 may include a buffer terminal BT, a third TSV TSV3, and an RC structure. The buffer terminal BT may be included in the upper surface unit 200. The third TSV TSV3 may penetrate through the substrate 400. The RC structure may be included in the lower surface unit 600 and provide an RC delay.

The buffer terminal BT may be connected to an output terminal of a first flip-flop FF1 and an input terminal of a second flip-flop FF2 described with reference to FIG. 1. For example, referring to FIG. 1 and FIG. 5, the output terminal of the first flip-flop FF1 is illustrated as an input terminal IN, and the input terminal of the second flip-flop FF2 is illustrated as an output terminal OUT.

The third TSV TSV3 may be disposed in the substrate 400. The third TSV TSV3 may be connected to the buffer terminal BT. Additionally, the RC structure included in the lower surface unit 600 may be electrically connected to the buffer terminal BT through the third TSV TSV3. In the example of FIG. 5, the RC structure is illustrated as an equivalent circuit including a third resistor R3 and a second capacitor C2. Parameters of the third resistor R3 and the second capacitor C2 may vary, depending on the design of the RC structure, and the RC delay provided by the hold buffer HBUF2 may vary.

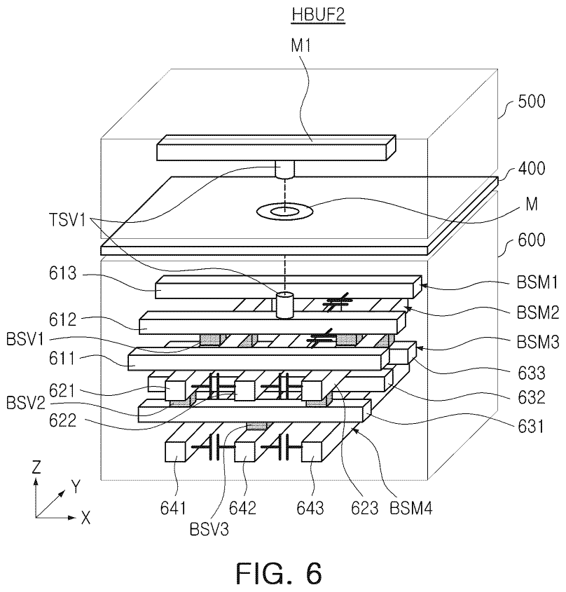

FIG. 6 is a view illustrating in detail a hold buffer according to an example embodiment of the present disclosure.

A hold buffer HBUF2 illustrated in FIG. 6 may correspond to the hold buffer HBUF2 described with reference to FIG. 5. Referring to FIG. 6, an upper surface unit 500 may include a buffer terminal BT. In an example embodiment, the buffer terminal BT may be provided by a metal wire M1. The buffer terminal BT may be electrically connected to the RC structure by the third TSV TSV3 penetrating through the substrate 400. FIG. 6 illustrates a metal M penetrating through a substrate 400 and formed around the third TSV TSV3.

The RC structure may include first to fourth conductive patterns BSM1, BSM2, BSM3 and BSM4 and the first to third vias BSV1, BSV2 and BSV3 may be alternately stacked on the substrate 400 in a lower surface unit 600 in a direction opposite to a third direction (Z-direction). The first to fourth conductive patterns BSM1 to BSM4 may be disposed on conductive layers on different levels.

Similarly to that described with reference to FIG. 3, the first to fourth conductive patterns BSM1 to BSM4 may extend in intersecting directions in which conductive patterns disposed in neighboring conductive layers intersect each other. The first conductive patterns BSM1 disposed on an uppermost layer of the lower surface unit 600 may extend in a direction, parallel to a metal wire M1 disposed on a lowermost layer of the upper surface unit 500. However, the present disclosure is not limited thereto.

The RC structure may include signal conductive patterns and power conductive patterns. The signal conductive patterns may be connected to a data path. The power conductive patterns may be connected to a power source. For example, the power may be VDD power or VSS power. In each conductive layer, the signal conductive patterns and the power conductive patterns may be arranged alternately with each other.

For example, the first conductive patterns BSM1 may include a signal conductive pattern 612 connected to the buffer terminal BT through the third TSV TSV3 and power conductive patterns 611 and 613 connected to the power source.

The second conductive patterns BSM2 may include signal conductive patterns 621 and 623 connected to the signal conductive pattern 612 through the first via BSV1, and a power conductive pattern 622 connected to the power source.

The third challenge patterns BSM3 may include signal conductive patterns 631 and 633 connected to the signal conductive patterns 621 and 623 through the second via BSV2, and power conductive patterns 632 connected to the power source.

The fourth conductive patterns BSM4 may include signal conductive patterns 642 connected to the signal conductive pattern 631 and 633 through the third via BSV3 and power conductive patterns 641 and 643 connected to the power source.

In FIG. 6, an electrical connection between the power conductive patterns 611, 613, 622, 632, 641 and 643 may be omitted.

An insulating layer may be disposed surrounding the signal conductive patterns and the power conductive patterns of the RC structure. The signal conductive patterns may provide resistance components. The signal conductive patterns, the insulating layer, and the power conductive patterns may provide capacitance.

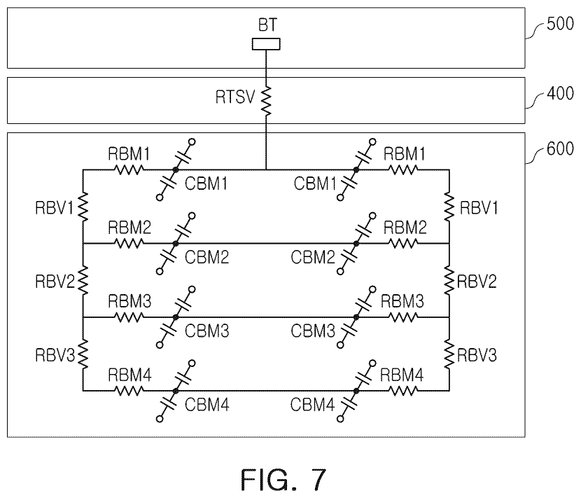

FIG. 7 is a view illustrating an equivalent circuit of the hold buffer of FIG. 6.

Referring to FIG. 6 and FIG. 7, the third TSV TSV3 may include a resistance component RTSV. Among the first to fourth conductive patterns BSM1 to BSM4, the signal conductive patterns may provide resistance components RBM1, RBM2, RBM3 and RBM4, respectively. Additionally, the first to third vias BSV1 to BSV3 connected to the signal conductive patterns may provide resistance components RBV1, RBV2 and RBV3, respectively.

The signal conductive patterns and the power conductive patterns included in the first conductive patterns BSM1 may provide capacitance CBM1 together with the insulating layer between the first conductive patterns BSM1. Similarly, the second conductive patterns BSM2 may provide capacitances CBM2, together with the insulating layer. The third conductive patterns BSM3 may provide third capacitances CBM3, together with the insulating layer. The fourth conductive patterns BSM4 may provide fourth capacitances CBM4, together with the insulating layer.

Resistance components and capacitances shown in FIG. 7 may provide an RC delay between the input terminal IN and the output terminal OUT described with reference to FIG. 5.

In the examples of FIG. 6 and FIG. 7, the signal conductive patterns of each conductive layer may have a structure in which all signal conductive patterns of neighboring conductive layers may be connected. For example, the signal conductive pattern 612 may be connected to the signal conductive patterns 621 and 623, and the signal conductive patterns 631 and 633 without interruption in a direction in which the signal conductive pattern 612 extends. The structures illustrated in FIG. 6 and FIG. 7 may provide high capacitance and may provide high RC delay. For example, the structures illustrated in FIG. 6 and FIG. 7 may provide high capacitance and may provide high RC delay as compared to a structure in which some of the signal conductive patterns are not connected to some of the signal conductive patterns of neighboring conductive layers.

However, the present disclosure is not limited to the structures illustrated in FIG. 6 and FIG. 7. For example, to provide a set RC delay, the hold buffer may have a structure in which some of the signal conductive patterns may not be connected to some of the signal conductive patterns of neighboring conductive layers.

According to an example embodiment of the present disclosure described with reference to FIG. 6 and FIG. 7, the RC structure of the hold buffer may include four layers of conductive patterns BSM1 to BSM4. However, the present disclosure is not limited thereof. For example, the hold buffer may include conductive patterns included in three or less conductive layers, or may include conductive patterns included in five or more conductive layers.

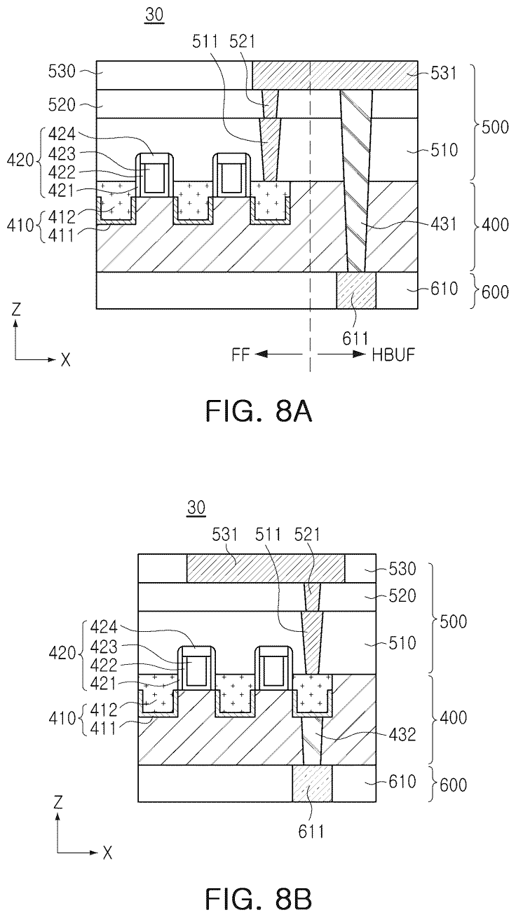

In the examples of FIGS. 2 to 7, an example embodiment of the present disclosure may be implemented by taking as an example a case in which at least one TSV included in the hold buffer is connected to the output terminal of the first flip-flop FF1 and the input terminal of the second flip-flop FF2 by a metal layer formed on an upper surface unit of the substrate. However, the present disclosure is not limited thereto. Hereinafter, with reference to FIG. 8A and FIG. 8B, various embodiments in which the TSV included in the hold buffer and the output terminal of the first flip-flop FF1 and the input terminal of the second flip-flop FF2 may be connected will be described.

FIG. 8A and FIG. 8B are cross-sectional views illustrating a portion of a semiconductor device according to example embodiments of the present disclosure.

FIG. 8A illustrates a portion of a substrate 400, an upper surface unit 500 at a frontside the semiconductor device 30, and a lower surface unit 600 at a backside of the semiconductor device 30 as described with reference to FIG. 5, FIG. 6, and FIG. 7. Specifically, FIG. 8A illustrate a portion of a region forming a flip-flop FF and a portion of a region forming a hold buffer HBUF of the semiconductor device 30.

Referring to FIG. 8A, active regions 410 and gate structures 420 may be formed on the substrate 400. A channel region may be defined between adjacent active regions 410 in the first direction (X-direction), and at least one of the gate structures 420 may be disposed on the channel region.

Each of the gate structures 420 may include a gate spacer 421, a gate insulating layer 422, a gate conductive layer 423, and a capping layer 424. However, according to example embodiments, the structure of each gate structure 420 may be modified in various manners. For example, in consideration of a threshold voltage of each semiconductor component, a thickness and/or a material of the gate insulating layer 422 may vary, or a material and/or a stacked structure of the gate conductive layer 423 may vary.

An upper surface upper 500 may include a plurality of insulating layers 510, 520 and 530. The insulating layer 510 may be disposed on the active regions 410 and the gate structures 420. Gate contacts and active contacts may be disposed in the insulating layer 510. In an example of FIG. 8A, an active contact 511 in contact with an upper surface of the active region 410 is illustrated. Gate vias and active vias may be disposed in the insulating layer 520. In the example of FIG. 8A, an active via 521 in contact with an upper surface of the active contact 511 is illustrated. Frontside conductive patterns 531 may be disposed in the insulating layer 530.

A lower surface upper 600 may include an insulating layer 610. A power conductive pattern 611 may be disposed in the insulating layer 610.

The flip-flop FF may be formed by connecting the active regions 410 and the gate structures 420 to the frontside conductive patterns 531 and conductive patterns (e.g., the power conductive pattern 611) of the lower surface unit 600 through one or more of gate contacts, active contacts, gate vias, or active vias.

The hold buffer HBUF may include an RC structure formed on the lower surface unit 600 and a TSV 431 penetrating through the substrate 400. The TSV 431 of the hold buffer HBUF may connect an input terminal or an output terminal of the flip-flop FF to the RC structure. FIG. 8A illustrates the power conductive pattern 611 in contact with the TSV 431, among the conductive patterns constituting the RC structure.

According to an example embodiment of the present disclosure, the TSV 431 may be connected to an active region or a gate structure providing an output terminal or an input terminal of the flip-flop FF through the frontside conductive patterns 531, the active via 521, and the active contact 511 formed on the upper surface unit 500.

For example, in the case of the hold buffer HBUF1 as described with reference to FIG. 2, FIG. 3, and FIG. 4, a first TSV TSV1 may be connected to an active region providing the output terminal of the first flip-flop FF1 described with reference to FIG. 1 through a conductive pattern formed on the frontside, and a second TSV TSV2 may be connected to a gate structure providing the input terminal of the second flip-flop FF2 described with reference to FIG. 1 through a conductive pattern formed on the frontside.

Additionally, in the case of the hold buffer HBUF2 as described with reference to FIG. 5, FIG. 6, and FIG. 7, a third TSV TSV3 may be connected to the active region providing the output terminal of the first flip-flop FF1 and the gate structure providing the input terminal of the second flip-flop FF2 through a conductive pattern formed on the frontside.

FIG. 8B illustrates a portion of the substrate 400, the upper surface unit 500, and the lower surface unit 600 of the semiconductor device 30 as described with reference to FIG. 5, FIG. 6, and FIG. 7. Active regions 410 and gate structures 420 as described with reference to FIG. 8A may be formed on the substrate 400. Additionally, the active contact 511 and the active via 521 as described with reference to FIG. 8A may be disposed in the upper surface unit 500.

The hold buffer may include an RC structure formed in the lower surface unit 600 and a TSV 432 penetrating through the substrate 400. The TSV 432 of the hold buffer HBUF may connect the input terminal or the output terminal of the flip-flop FF to the RC structure. FIG. 8B illustrates a power conductive pattern 611 disposed in contact with the TSV 432 among the conductive patterns forming the RC structure.

According to an example embodiment of the present disclosure, the TSV 432 may be connected to the active region providing an input terminal of the flip-flop FF in the substrate 400. For example, an upper surface of the TSV 432 may be in contact with a lower surface of the active region 410 in the substrate 400.

For example, the TSV 432 may be in contact with the active region providing the output terminal of the first flip-flop FF1 described with reference to FIG. 1 in the substrate 400.

According to an example embodiment of FIG. 8B, an area occupied by the hold buffer on the frontside of the substrate may be further reduced.

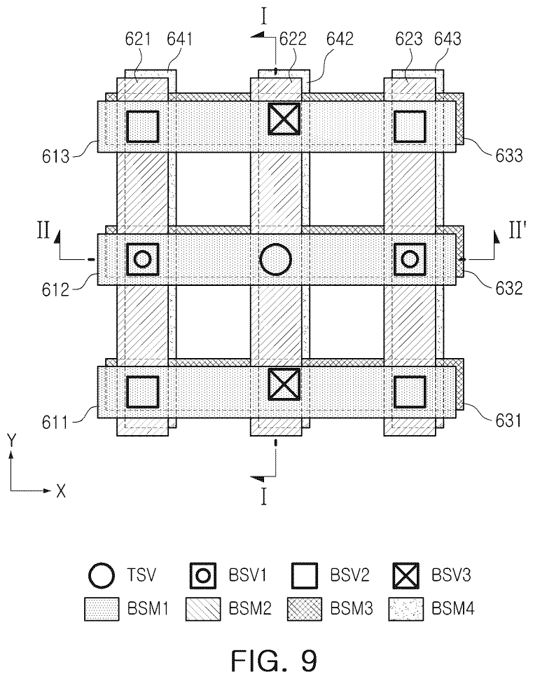

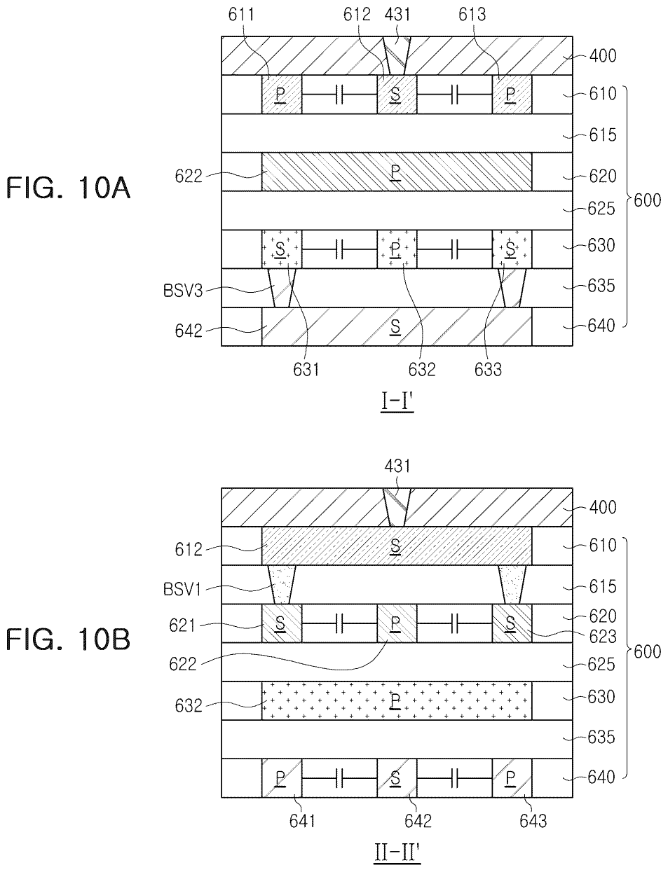

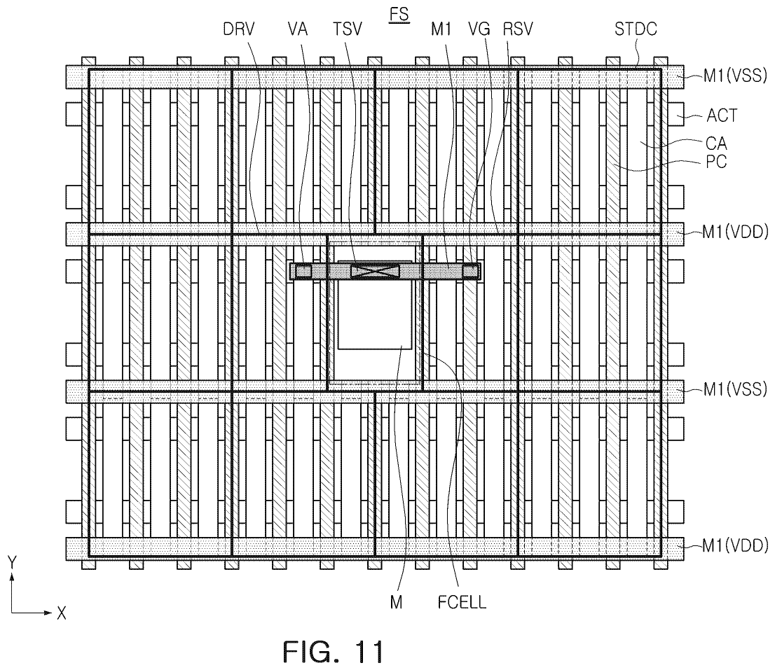

For example, the RC structure included in the hold buffer may have an expanded unit structure depending on the size of the RC delay of the hold buffer. Hereinafter, before the extended structure of the RC structure is explained in detail, an example of the unit structure of the RC structure is explained with reference to FIG. 9, FIG. 10A, and FIG. 10B.

FIG. 9 is a plan view illustrating a backside of a semiconductor device according to an example embodiment of the present disclosure.

FIG. 9 is a plan view of a unit structure of an RC structure included in a hold buffer, when viewed from an upper surface of a substrate to a direction facing a backside thereof. The unit structure illustrated in FIG. 9 corresponds to an example RC structure of the lower surface unit 600 described with reference to FIG. 6.

First to fourth conductive patterns BSM1 to BSM4 may extend in directions that conductive patterns disposed in neighboring conductive layers intersect each other. The first conductive patterns BSM1 and the third conductive patterns BSM3 may be disposed in substantially a same position in a plane, parallel to an upper surface of a substrate, and the second conductive patterns BSM2 and the fourth conductive patterns BSM4 may be disposed in substantially a same position in a plane, parallel to the upper surface of the substrate. However, for convenience of description in conjunction with FIG. 9, the first conductive patterns BSM1 and the third conductive patterns BSM3, and the second conductive patterns BSM2 and the fourth conductive patterns BSM4 are illustrated as being slightly misaligned. Additionally, an insulating layer disposed between the first to fourth conductive patterns BSM1 to BSM4 is omitted.

The first to fourth conductive patterns BSM1 to BSM4 may be electrically connected through first to third vias BSV1 to BSV3. In FIG. 9, among the vias connecting the first to fourth conductive patterns BSM1 to BSM4, vias connecting the signal conductive patterns are illustrated. For example, other vias may be omitted from a structure illustrated shown in FIG. 9. A signal conductive pattern 612 may be in contact with a TSV, and signal conductive patterns 621, 623, 631, 633 and 642 may be connected to the signal conductive pattern 612 through the first to third vias BSV1 to BSV3 illustrated in FIG. 9. Power conductive patterns 611, 613, 622, 632, 641 and 643 may be electrically connected to a power source according to the structure illustrated shown in FIG. 9.

Signal conductive patterns may provide a resistive component. Additionally, the signal conductive patterns, the insulating layer, and the power conductive patterns may provide capacitance.

FIG. 10A and FIG. 10B are cross-sectional views taken along lines II-I′ and II-II′ of FIG. 9, respectively.

Referring to FIG. 10A, a lower surface unit 600 may include a plurality of insulating layers 610, 615, 620, 625, 630, 635 and 640. A plurality of conductive patterns BSM1 to BSM4 and a plurality of vias BSV1 to BSV3 may be formed in each of the plurality of insulating layers 610 to 640. FIG. 10A illustrates some conductive patterns 611, 612, 613, 622, 631, 632 and 633 among a plurality of conductive patterns. The illustrated conductive patterns are illustrated as signal conductive patterns S and power conductive patterns P.

According to an example embodiment of the present disclosure, the signal conductive patterns S, the power conductive patterns P, and an insulating layer therebetween may provide capacitance. In FIG. 10A, the capacitance formed between the first conductive patterns BSM1, including signal conductive pattern 612, and power conductive patterns 611 and 613, and the capacitance formed between the third conductive patterns BSM3, including signal conductive patterns 631 and 633, and power conductive pattern 632, are illustrated.

Referring to FIG. 10B, similarly to FIG. 10A, some of a plurality of insulating layers 610 to 640, a plurality of conductive patterns BSM1 to BSM4, and a plurality of vias BSV1 to BSV3 are illustrated.

According to an example embodiment of the present disclosure, the signal conductive patterns S, the power conductive patterns P, and an insulating layer therebetween may provide capacitance. In FIG. 10B, a capacitance formed between the second conductive patterns BSM2, including signal conductive patterns 621 and 623, and power conductive pattern 62, and a capacitance formed between the fourth conductive patterns BSM4, including signal conductive pattern 642, and power conductive patterns 641 and 643, are illustrated.

According to an example embodiment of the present disclosure, an example of the RC structure may have a structure in which unit structures such as those described with reference to FIG. 9, FIG. 10A, and FIG. 10B may be repeated according to a size of an RC delay used for a hold buffer.

According to an example embodiment of the present disclosure, at least one of a length of the conductive patterns in each of the plurality of conductive layers, a separation distance between the conductive patterns, or a number of the plurality of conductive layers affects an RC delay of the RC structure.

With an increase in the size of the RC delay used for the hold buffer, an area occupied by the RC structure in the lower surface unit 600 may increase. However, the area occupied by the hold buffer on the upper surface unit 500 may be fixed to the area occupied by the TSV regardless of the size of the RC delay. Accordingly, semiconductor components may be integrated (e.g., highly integrated) in the upper surface unit 500 regardless of the size of the RC delay.

Hereinafter, an example embodiment of the present disclosure will be described by taking as an example a case in which structures of the upper surface unit 500 and the lower surface unit 600 of the hold buffer may be defined as standard cells.

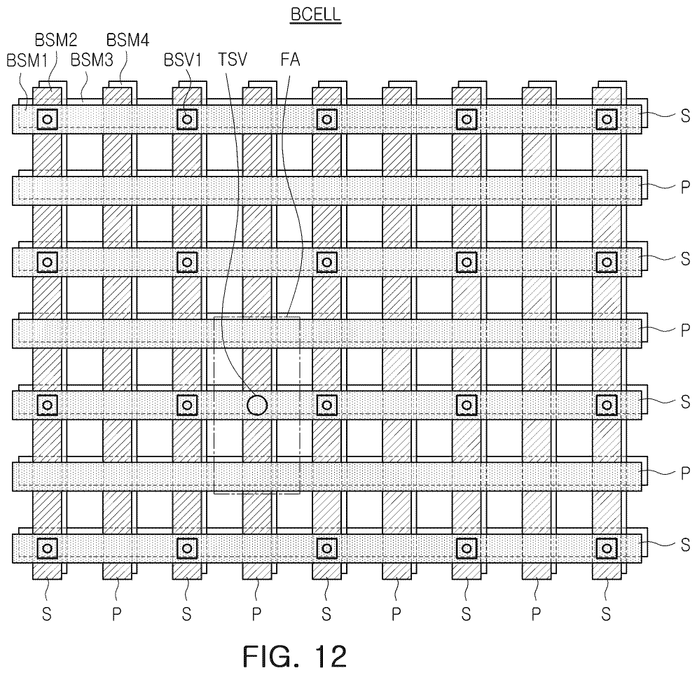

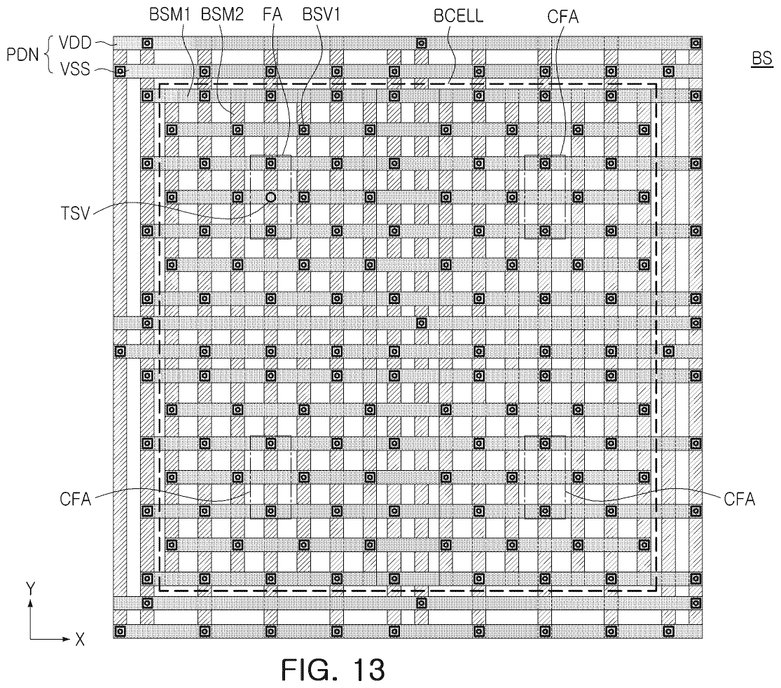

FIG. 11 and FIG. 12 are views illustrating a case in which a semiconductor device according to an example embodiment of the present disclosure includes standard cells. FIG. 11 is a plan view illustrating a frontside of a semiconductor device according to an example embodiment of the present disclosure. FIG. 12 is a plan view illustrating a backside of a semiconductor device according to an example embodiment of the present disclosure.

A semiconductor device may include semiconductor components formed on a semiconductor substrate and wires for connecting the semiconductor components, and may be designed by disposing and connecting standard cells, which may be predefined in a library.

Referring to FIG. 11, a frontside FS of the semiconductor device may include standard cell regions STDC. A standard cell may be disposed in each of the standard cell regions STDC.

The semiconductor device may include a wiring pattern M1, power wires M1 (VDD) and power wires M1 (VSS) extending in a first direction (X-direction). The power wires M1 (VDD) and power wires M1 (VSS) may be a power source for purposes of a backside buffer cell according to an embodiment of the present disclosure. The power wires M1 (VDD) and power wires M1 (VSS) may be separated from each other in a second direction (Y-direction), intersecting the first direction. For example, the power wires M1 (VDD) and M1 (VSS) may extend at boundaries between the standard cell regions STDC, or may traverse at least one of the standard cell regions STDC.

The power wires M1 (VDD) may be first power wires M1 (VDD) transmitting first power voltage VDD, and the power wires M1 (VSS) may be second power wires M1 (VSS) transmitting second power voltage VSS lower than the first power voltage VDD. The first power wires M1 (VDD) and the second power wires M1 (VSS) may be alternately arranged in the second direction.

Gate structures PC may extend in the second direction (Y-direction) and may be separated from each other in the first direction (X-direction). The gate structures PC may include gate structures and dummy gate structures, which may provide semiconductor components. For example, the gate structures PC disposed at the boundaries between the standard cell regions STDC may be dummy gate structures.

The active regions ACT may extend in the first direction (X-direction) and may be separated from each other in the second direction (Y-direction). The active regions ACT may be connected to active contacts CA adjacent to the gate structures.

A standard cell may include wiring patterns connected to at least one of gate structures PC or active contacts CA. The wiring patterns may provide a signal path that transmits input signals to the unit circuit provided by a standard cell.

Transistors included in each standard cell may be connected to each other to provide a unit circuit. For example, each of the standard cells may provide circuits such as an inverter, a NAND gate, an OR gate, an OR-AND-INVERTER (OAI) circuit, an AND-OR-INVERTER (AOI) circuit, a flip-flop, or a latch.

The unit circuit provided by the standard cell may receive a specified input signal and may discharge an output signal corresponding to the input signal. The input signal may be input to at least one of the gate structures PC through at least one of lower wiring patterns. The output signal may be output through at least one of the active regions ACT. Accordingly, the output signal may be output from at least one of the active contacts CA.

According to an example embodiment of the present disclosure, a frontside buffer cell FCELL at a frontside of the hold buffer may be defined in a standard cell library. The frontside buffer cell FCELL may include at least one TSV of the hold buffer. In an example of FIG. 11, a metal M formed around the TSV is also illustrated.

In an example embodiment, the TSV may be connected to an input terminal of the hold buffer and an output terminal of the hold buffer through the wiring pattern M1. FIG. 11 illustrates a driver cell DRV providing the input terminal of the hold buffer and a receiver cell RSV providing the output terminal of the hold buffer. For example, the driver cell DRV may be electrically connected to the output terminal of the first flip-flop FF1 described with reference to FIG. 1, and the receiver cell RSV may be electrically connected to the input terminal of the second flip-flop FF2 described with reference to FIG. 1. A TSV may be connected to an active contact CA of the driver cell DRV through the wiring pattern M1 and an active via VA, and may be connected to a gate structure PC of the receiver cell RSV through the wiring pattern M1 and a gate via VG.

Referring to FIG. 12, a backside of a semiconductor device may include a backside buffer cell BCELL of a backside of the hold buffer. An area occupied by the frontside illustrated in FIG. 11 on a frontside of the substrate may overlap an area occupied by the backside illustrated in FIG. 12 on a backside of the substrate.

The backside buffer cell BCELL may have a structure in which a unit structure described with reference to FIG. 9, FIG. 10A, and FIG. 10B may be repeated in the first direction (X-direction) and the second direction (Y-direction) according to a determined RC delay. In FIG. 12, the first to fourth conductive patterns BSM1 to BSM4, the TSV, and the first vias BSV1 connecting the signal conductive patterns are illustrated. That is, embodiments of the present disclosure are not limited thereto, and the backside illustrated in FIG. 12 may include other components.

According to an example embodiment, a number of conductive layers of the RC structure may increase or decrease as compared to the unit structure according to the determined RC delay. Accordingly, a separation distance between the conductive patterns in each conductive layer may vary, depending on the determined RC delay.

Vias connecting the first to fourth conductive patterns BSM1 to BSM4 may be formed so that signal conductive patterns and power conductive patterns among the conductive patterns included in the same conductive layer may be alternately arranged. FIG. 12 indicates whether each of the first and second conductive patterns BSM1 and BSM2 is a signal conductive pattern S or a power conductive pattern P.

The signal conductive patterns S may provide a resistance component. The signal conductive patterns of the backside buffer cell BCELL may be longer than the signal conductive patterns included in the unit structure, and the RC structure of the backside buffer cell BCELL may provide a higher resistance component than the unit structure.

The signal conductive patterns S, the power conductive patterns P, and the insulating layer between the signal conductive patterns S and the power conductive patterns P may provide capacitance. Since a surface area of the signal conductive patterns S and the power conductive patterns P providing the capacitance may be larger than a surface area of the signal conductive patterns and the power conductive patterns included in the unit structure, the RC structure of the backside buffer cell BCELL may provide higher capacitance than the unit structure.

In an example embodiment, a plurality of backside buffer cells of which unit structures may be repeated by different numbers depending on the RC delay may be defined in the standard cell library. To design an integrated circuit, a backside buffer cell of plurality of backside buffer cells may be selected depending on the RC delay selected for each of the hold buffers.

According to an example embodiment of the present disclosure, the RC structure formed of a metal and an insulating layer may be used to provide a delay in the hold buffer, and the RC structure may be disposed on a backside, and an area occupied by the hold buffer on the frontside may be reduced. Referring to FIG. 11 and FIG. 12, an area of the backside buffer cell BCELL may be larger than an area of the frontside buffer cell FCELL. Furthermore, in an area overlapping the back buffer cell BCELL in the frontside FS, in addition to the frontside buffer cell FCELL, several additional standard cells may be further disposed. Accordingly, the degree of integration of the semiconductor device may be improved.

Meanwhile, as described herein, a PDN may be formed on a backside of the semiconductor device. The PDN may include power wiring patterns formed in a determined pattern, such as a grid pattern.

According to an example embodiment of the present disclosure, the RC structure included in the hold buffer may be formed in a shape crossing the power wiring patterns. Accordingly, RC structures that may provide a set RC delay may be designed regardless of an arrangement of power wiring patterns.

FIG. 13 is a plan view illustrating a backside of a semiconductor device according to an example embodiment of the present disclosure.

A backside BS of a substrate of a semiconductor device may include a PDN and a backside buffer cell BCELL. The PDN and the back buffer cell BCELL may be formed over a plurality of conductive layers. For example, when the back buffer cell BCELL has conductive patterns formed on four conductive layers, the PDN may also be formed over four conductive layers. However, FIG. 13 exemplarily illustrates a first conductive layer having first conductive patterns BSM1, a second conductive layer having second conductive patterns BSM2, and first vias BSV1 electrically connecting the first conductive patterns BSM1 and the second conductive patterns BSM2. That is, embodiments of the present disclosure are not limited thereto, and the backside illustrated in FIG. 13 may include other components.

The PDN may include first power wiring patterns for transmitting first power voltage VDD, and second power wiring patterns for transmitting second power supply voltage VSS that may be lower than the first power supply voltage.

In the example of FIG. 13, the PDN may be formed in a grid pattern. The grid pattern may include pairs of power wiring patterns extending in the first direction (X-direction) and spaced apart from each other in the second direction (Y-direction) in the same conductive layer as the first conductive patterns BSM1, and pairs of power wiring patterns extending in the second direction (Y-direction) and spaced apart from each other in the first direction (X-direction) in the same conductive layer as the second conductive patterns BSM2. The pairs of the power wiring patterns may each include first and second power wiring patterns. Power wiring patterns disposed on different conductive layers may be electrically connected through vias.

According to an example embodiment of the present disclosure, the backside buffer cell BCELL may be formed in a shape crossing the PDN.

As described with reference to FIG. 12, the backside buffer cell BCELL may include a plurality of conductive patterns formed on each of a plurality of conductive layers and a plurality of vias electrically connecting the plurality of conductive patterns formed on different conductive layers. FIG. 13 illustrate first vias BSV1 electrically connecting first and second conductive patterns BSM1 and BSM2 to power wiring patterns.

According to an example embodiment of the present disclosure, at least some of the signal conductive patterns may be formed to cross the PDN. In the example of FIG. 13, the first conductive patterns BSM1 may overlap some of the first power wiring patterns and/or the second power wiring patterns included in the second conductive layer in a plane parallel to the backside of the substrate. Additionally, the second conductive patterns BSM2 may overlap some of the first power wiring patterns and/or the second power wiring patterns included in the first conductive layer in a plane parallel to the backside of the substrate.

According to an example embodiment of the present disclosure, signal conductive patterns of the backside buffer cell BCELL can be electrically connected to each other regardless of the PDN formed in a grid pattern. Accordingly, even if the TSV is in contact with any portion of the signal conductive patterns among the first conductive patterns BSM1, an RC structure of the backside buffer cell BCELL may function as a hold buffer.

In the example of FIG. 13, an example of a position in which a TSV may be disposed is illustrated. Additionally, an example of a region FA in which a frontside buffer cell may be placed around the TSV is illustrated. However, TSVs may be placed in various positions, and the frontside buffer cells may also be disposed in various regions. In FIG. 13, several examples of candidate regions CFAs in which the frontside buffer cells may be disposed are illustrated.

According to an example embodiment of the present disclosure, even when the size of the backside buffer cell BCELL is larger than a region defined by the grid pattern of the PDN, the frontside buffer cells of the hold buffer may be freely disposed, and the degree of freedom in integrated circuit design may be improved.

While example embodiments have been illustrated and described above, it will be configured as apparent to those skilled in the art that modifications and variations may be made without departing from the scope of the present disclosure as defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a plurality of standard cells disposed on a frontside of a substrate, and respectively including at least one gate structure and at least one active region;
a frontside buffer cell disposed on the frontside of the substrate and between at least some of the plurality of standard cells, and including at least one a Through-Silicon Via (TSV) penetrating through the substrate; and
a backside buffer cell disposed on a backside of the substrate,
wherein the backside buffer cell comprises:
a plurality of conductive layers disposed at different levels on the backside of the substrate;
a plurality of vias connecting the plurality of conductive layers and disposed between the plurality of conductive layers; and
an insulating layer surrounding the plurality of conductive layers and the plurality of vias, and
wherein each of the plurality of conductive layers includes signal conductive patterns electrically connected to the at least one TSV, and power conductive patterns electrically connected to a power source.

2. The semiconductor device of claim 1, wherein at least some of the plurality of standard cells form a first flip-flop and a second flip-flop,
the frontside buffer cell includes a first frontside buffer cell including a first TSV and a second frontside buffer cell including a second TSV, and
an output terminal of the first flip-flop is connected to the first TSV, and an output terminal of the second flip-flop is connected to the second TSV.

3. The semiconductor device of claim 1, wherein at least some of the plurality of standard cells form a first flip-flop and a second flip-flop, and the at least one TSV is connected to an output terminal of the first flip-flop and an input terminal of the second flip-flop.

4. The semiconductor device of claim 3, wherein the at least one TSV is connected to an active region of the at least one active region including the output terminal of the first flip-flop and a gate structure of the at least one gate structure including the input terminal of the second flip-flop, through a conductive pattern disposed on the frontside of the substrate.

5. The semiconductor device of claim 3, wherein the at least one TSV is disposed in the substrate and is connected to the active region including the output terminal of the first flip-flop.

6. The semiconductor device of claim 1, wherein the frontside buffer cell overlaps the backside buffer cell in a plane parallel to the frontside of the substrate.

7. The semiconductor device of claim 1, wherein a size of an area occupied by the backside buffer cell on the backside of the substrate is larger than a size of an area occupied by the frontside buffer cell on the frontside of the substrate.

8. The semiconductor device of claim 7, wherein the size of the area occupied by the backside buffer cell on the backside of the substrate includes a size of an RC (Resistance-Capacitance) structure configured to provide an RC delay of the backside buffer cell.

9. The semiconductor device of claim 1, wherein the plurality of conductive layers comprise:
first power wiring patterns transmitting a first power voltage; and
second power wiring patterns transmitting a second power voltage lower than the first power voltage.

10. The semiconductor device of claim 9, wherein each of the power conductive patterns is electrically connected to one of the first power wiring patterns or the second power wiring patterns.

11. The semiconductor device of claim 9, wherein the plurality of conductive layers comprise:
a first conductive layer nearest to the backside of the substrate among the plurality of conductive layers; and
a second conductive layer disposed on the first conductive layer, wherein the first conductive layer is disposed between the backside of the substrate and the second conductive layer.

12. The semiconductor device of claim 11, wherein at least some of the signal conductive patterns included in the first conductive layer have a region overlapping at least some of the first power wiring patterns and the second power wiring patterns included in the second conductive layer in a plane parallel to the backside of the substrate, and
at least some of the signal conductive patterns included in the second conductive layer have a region overlapping at least some of the first power wiring patterns and the second power wiring patterns included in the first conductive layer in the plane parallel to the backside of the substrate.

13. The semiconductor device of claim 1, wherein at least one of the signal conductive patterns included in a first conductive layer nearest to the backside of the substrate, among the plurality of conductive layers, is in contact with the at least one TSV.

14. The semiconductor device of claim 1, wherein the signal conductive patterns and the power conductive patterns included in the plurality of conductive layers form a metal mesh in the insulating layer.

15. A semiconductor device, comprising:
a substrate;
a Through-Silicon Via (TSV) penetrating through the substrate and electrically connected to an output terminal of a first flip-flop disposed on a frontside of the substrate and an input terminal of a second flip-flop disposed on the frontside of the substrate; and
a Resistance-Capacitance (RC) structure disposed on a backside of the substrate,
wherein the RC structure comprises:
a plurality of conductive layers respectively including a plurality of conductive patterns;
a plurality of vias connecting the plurality of conductive patterns between the plurality of conductive layers; and
an insulating layer surrounding the plurality of conductive layers,
wherein conductive patterns of neighboring conductive layers, among the plurality of conductive layers, extend in a direction in which the conductive patterns intersect each other, and
the conductive patterns of each of the plurality of conductive layers include signal conductive patterns electrically connected to the TSV, and power conductive patterns electrically connected to a power source, and the signal conductive patterns and power conductive patterns are arranged alternately.

16. The semiconductor device of claim 15, wherein an active region including the output terminal of the first flip-flop and a gate structure including the input terminal of the second flip-flop are electrically connected to the TSV through a first conductive pattern disposed on the frontside of the substrate.

17. The semiconductor device of claim 15, wherein a first active region is disposed on the substrate in contact with the TSV and includes the output terminal of the first flip-flop.

18. The semiconductor device of claim 15, wherein at least one of a length of the conductive patterns in each of the plurality of conductive layers, a separation distance between the conductive patterns, or a number of the plurality of conductive layers affects an RC delay of the RC structure.

19. A semiconductor device, comprising:
a substrate;
a first Through-Silicon Via (TSV) penetrating through the substrate and connected to an output terminal of a first flip-flop disposed on a frontside of the substrate;
a second TSV penetrating through the substrate and connected to an input terminal of a second flip-flop disposed on the frontside of the substrate; and
a Resistance-Capacitance (RC) structure disposed on a backside of the substrate,
wherein the RC structure comprises:
a plurality of conductive layers stacked on the backside of the substrate and respectively including a plurality of conductive patterns;
a plurality of vias connecting a plurality of conductive patterns between the plurality of conductive layers; and
an insulating layer surrounding the plurality of conductive layers and the plurality of vias,
wherein conductive patterns of neighboring conductive layers of the plurality of conductive layers extend in directions in which the conductive patterns intersect each other, and
the plurality of conductive layers include signal conductive patterns electrically connected to the first TSV and the second TSV, and power conductive patterns electrically connected to a power source.

20. The semiconductor device of claim 19,
wherein the plurality of conductive layers include a first conductive layer and second conductive layers disposed between the first conductive layer and the backside of the substrate,
each of the second conductive layers includes first signal conductive patterns of the signal conductive patterns connected to the first TSV and second signal conductive patterns of the signal conductive patterns connected to the second TSV, and the first signal conductive patterns and the second signal conductive patterns are separated from each other, and
the first conductive layer includes a signal conductive pattern of the signal conductive patterns electrically connecting the first signal conductive patterns and the second signal conductive patterns.
